(19) United States
(12) Patent Application Publication
(10) Pub. No.: US 2026/0196822 A1
(43) Pub. Date: Jul. 9, 2026

(54) DETECTION OR PREVENTION OF ELECTRICAL SECONDARY ARC IN AN ELECTRIC POWER DELIVERY SYSTEM

(71) Applicant: Schweitzer Engineering Laboratories, Inc., Pullman, WA (US)

(72) Inventors: Thomas J. Morrell, Pullman, WA (US); Mark A. Talbott-Williams, Moscow, ID (US)

(73) Assignee: Schweitzer Engineering Laboratories, Inc., Pullman, WA (US)

(21) Appl. No.: 19/010,478

(22) Filed: Jan. 6, 2025

(51) Int. Cl. H02H 3/16; G01R 19/10; G01R 19/165; G01R 19/25; G01R 31/08; H02H 1/00

(52) U.S. Cl. CPC H02H 3/16; G01R 19/10; G01R 19/16576; G01R 19/2513; G01R 31/086; H02H 1/0015

(57) ABSTRACT

Systems, methods, and devices for detecting an electrical secondary arc across a transition point in an electric power delivery system are provided. An intelligent electronic device (IED) for an electric power delivery system may include data processing circuitry and machine-readable media including instructions that, when executed by the data processing circuitry, cause the IED to perform operations several operations. The operations may include comparing a first electrical measurement across a transition point in the electric power delivery system measured at a first time with a second electrical measurement across the transition point measured at a second time; and identifying an occurrence of an electrical secondary arc across the transition point when the second electrical measurement at the second time is greater than the first electrical measurement at the first time by more than a threshold.

### BACKGROUND

This disclosure relates to detecting or preventing the occurrence of an electrical arc in a power delivery system by monitoring changes in voltage difference over time.

Electric power delivery systems deliver electricity from generators to electrical loads. Electrical arcs in an electric power delivery system are undesirable phenomena that may result due to a fault that occurs in the electric power delivery system. Electrical primary arcs occur when electricity rapidly discharges through two electrical conductors, whereas electrical secondary arcs occur when electricity rapidly discharges (e.g., sparks) between two electrical conductors. Indeed, electrical secondary arcs may continue even when the primary arc has been extinguished. Many systems have been developed to identify both electrical primary and secondary arcs. These include photosensors to identify flashes of light emitted during an electrical arcing event, audio sensors to measure the sound resulting from an electrical arcing event, or thermal ionization detectors to detect burning particulate matter resulting from an electrical arcing event. Yet these systems may struggle to detect an electrical arc in certain circumstances. For example, the light produced by an electrical secondary arc can be obstructed by densely packed cabling in switchboard applications. Switchboard cabinets may be well ventilated, so the particulates from an electrical arc that the thermal ionization detector would measure can be blown out of the cabinet before they can be detected. Moreover, an audio sensor may have difficulty detecting the sounds produced by an electrical arc over loud machinery or other equipment.

### BRIEF DESCRIPTION OF THE DRAWINGS

FIG. 1 is a schematic diagram of an example of an electrical arc detection system that uses an intelligent electronic device (IED) to detect voltage changes over time at an electrical transition point in an electric power delivery system;

FIG. 2 is a schematic diagram of another example of an electrical secondary arc detection system that uses two IEDs to detect voltage changes over time at an electrical transition point in an electric power delivery system;

FIG. 3 is a flowchart of a method for detecting or preventing an electrical secondary arc based on a change in voltage difference across an electrical transition point;

FIG. 4 is a flowchart of a method for performing preventive maintenance to prevent an electrical secondary arc based on a change in voltage difference over time across an electrical transition point;

FIG. 5 is a flowchart of a method for detecting or preventing an electrical secondary arc based on a change in electrical frequency harmonics across an electrical transition point;

FIG. 6 is a flowchart of a method for performing preventive maintenance to prevent an electrical secondary arc based on a change in electrical frequency harmonics over time across an electrical transition point;

FIG. 7 is a plot relating to an example electrical arc illustrating changes in voltage difference across an electrical transition point over time when an electrical secondary arc occurs;

FIG. 8 is a plot relating to the example electrical arc of FIG. 7, illustrating the absolute value of the voltage difference across the electrical transition point when the electrical secondary arc occurs;

FIG. 9 is a plot relating to the example electrical arc of FIG. 7, illustrating an average percentage of harmonic signal across the electrical transition point before the electrical secondary arc occurs;

FIG. 10 is a plot relating to the example electrical arc of FIG. 7, illustrating that the average percentage of harmonic signal across the electrical transition point increases during the occurrence of the electrical secondary arc;

FIG. 11 is a flow diagram of a method for detecting incremental changes in voltage difference over time that may be used to detect a likely electrical secondary arc; and

FIG. 12 is a flow diagram of a method for detecting an electrical secondary arc based on incremental changes in voltage difference over time.

### DETAILED DESCRIPTION

An electrical secondary arc may be detected or predicted and prevented using electrical measurements instead of, or in addition to, sensors that detect light, sound, or particulate matter due to the electrical secondary arc. By monitoring changes in electrical measurements over time, an electrical secondary arc may be detected or predicted based on electrical signatures related to electrical arcs. For example, a rapid increase in the absolute voltage difference across an electrical transition point may signify that an electrical secondary arc is occurring across the electrical transition point. Similarly, a rapid increase in electrical frequency harmonics may also indicate that an electrical secondary arc is occurring across the electrical transition point. Indeed, a rapid increase in absolute voltage difference accompanied by a rapid increase in electrical frequency harmonics may increase the confidence that an electrical secondary arc is occurring. Monitoring these values over a longer time horizon may also allow for preventive maintenance to prevent electrical secondary arcs from occurring in the first place. Detecting an electrical secondary arc before it transitions into a fault may reduce potential equipment damage and plant shutdown time.

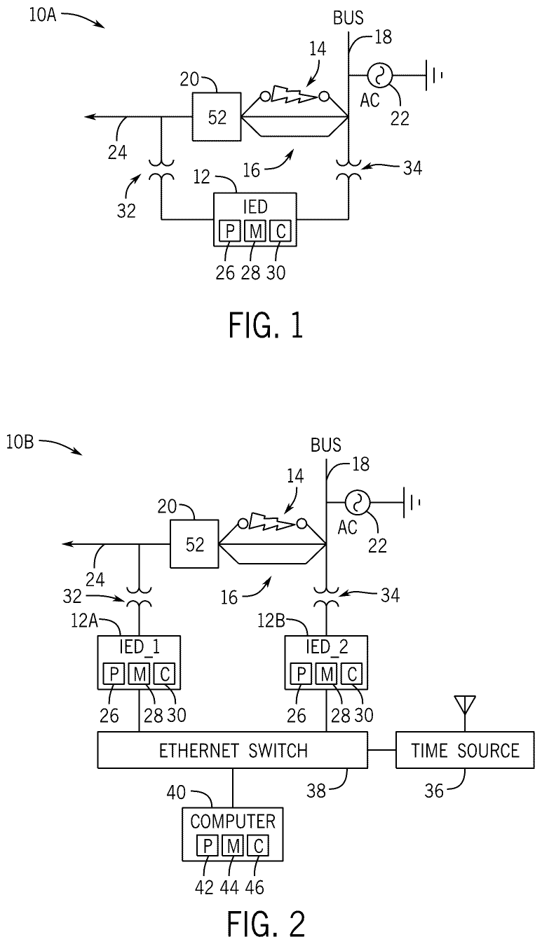

FIG. 1 illustrates an example of an electrical secondary arc detection or prevention system 10A that uses an intelligent electronic device (IED) 12 to detect or predict an electrical secondary arc 14 at a transition point 16 of an electric power delivery system. In the example of FIG. 1, the transition point 16 represents a set of conductors joining an electrical bus 18 to a breaker 20. Additionally or alternatively, there may be other transition points 16 where a set of conductors joins two electrical nodes in an electric power delivery system. Electrical secondary arcs 14 can occur across transition points 16 for a variety of reasons. Over time, the conductors of transition points 16 may age in a way that causes the impedance at the transition points 16 to increase. In harsh marine environments, for example, advanced aging at the transition points 16 may be caused by repeated thermal cycling, mechanical vibration, and corrosion from airborne salt. As the transition points 16 age, the impedance at the transition points 16 increase. And as impedance increases, the heat generated at the transition points 16 increase, which can cause the conductors of the transition points 16 to melt over time.

Returning to the particular example of FIG. 1, the transition point 16 connects the bus 18, which supplies electric power from a generator 22, to loads 24. The IED 12 may include any suitable control circuitry that may measure electrical signals traversing the transition point 16 and control the breaker 20 based on the measured electrical signals and/or based on a control signal from a supervisory control system (e.g., a supervisory control and data acquisition (SCADA) system). For example, the IED 12 may include a data processing system that includes processing circuitry 26 (e.g., a processor), memory or storage 28 (e.g., one or more tangible, non-transitory, machine-readable media) that store data and/or program instructions executable by the processing circuitry, as well as network communication circuitry 30 and/or input/output circuitry to communicate alarms and/or control components of the electric power delivery system such as the breaker 20, as well as to receive electrical measurements from electrical measurement devices on the electric power delivery system. For example, an alarm may be issued to alert an operator that the electrical secondary arc has been detected or the circuit breaker 20 may be tripped.

The IED 12 may detect or predict the electrical secondary arc 14 by monitoring voltage or current across the transition point 16. Potential transformers 32 and 34 may provide voltage measurements. Current transformers (not shown) may also be used to measure electrical current. When the electric power delivery system supplies multiphase (e.g., 3-phase) power, the electrical secondary arc 14 could occur on only one phase or on several phases at once. As such, the IED 12 may measure each phase separately to identify possible electrical secondary arcs 14 across different phases.

In the example of FIG. 1, a single IED 12 may be used to detect or predict the occurrence of an electrical secondary arc 14 at the transition point 16 by obtaining measurements on both sides of the transition point 16. Since the measurements are obtained by the same IED 12, they may be timestamped based on an internal clock of the IED 12 independent of other electronic devices. In other words, measurements obtained on the load 24 side of the transition point 16 and on the bus 18 side of the transition point 16 may be timestamped according to the same internal clock of the IED 12, which may or may not be based on a common time source with other electronic devices of the electric power delivery system to which the IED 12 belongs. Thus, using a single IED 12, measurements of the voltage difference across the transition point 16 may be known to correspond in time. Since the voltages on both sides of the transition point 16 are measured at the same time, any voltage differences between the two measurements may be understood to be due to the impedance of the transition point 16 rather than normal alternating current (AC) voltage changes over an electrical cycle. In this way, a single IED 12 may measure the voltage difference across the transition point 16 by obtaining electrical measurements on both sides of the transition point 16. This is true even if the system 10 does not include a common time source that is shared by any other IEDs 12 or other electronic devices that may be found in the electrical delivery system. The IED 12 may use the electrical measurements to detect the electrical secondary arc 14 based on changes in the measurements over time. For example, a rapid change in the voltage difference or harmonics across the transition point 16 may indicate the occurrence of the electrical secondary arc 14.

Additionally or alternatively, measurements may be obtained by multiple IEDs 12 synchronized to a common time source 36. One example is shown by an electrical secondary arc detection or prevention system 10B in FIG. 2. In the example of FIG. 2, a first IED (IED_1) 12A measures the voltage on the load 24 side of the transition point 16 via the potential transformer 32 and a second IED (IED_2) 12B measures the voltage on the bus 18 side of the transition point 16 via the potential transformer 34. Either the first IED 12A or the second IED 12B, or a different IED entirely, may control the breaker 20. The measurements obtained by the IEDs 12A and 12B may be correlated using timestamps from the common time source 36. The first IED 12A and the second IED 12B may receive a common time signal based on the common time source 36 via a communication network such as an Ethernet switch 38 (e.g., via IEEE 1588 precision time protocol (PTP)). The common time source 36 may be entirely locally generated or may derive from an external signal, such as a satellite network signal (e.g., a Global Positioning System (GPS) signal) or a terrestrial or marine radio signal. Additionally or alternatively, the IEDs 12A and 12B may respectively connect to separate clocking devices that derive the common time signal from an external signal (e.g., a satellite network signal or terrestrial or marine radio signal).

Electrical measurements from the IEDs 12A and 12B may be transmitted across the communication network (e.g., facilitated by the Ethernet switch 38) and provided to a separate computer 40 (e.g., an operator workstation, a main electric delivery power system controller, a SCADA system) and/or to one of the IEDs 12A or 12B. Additionally or alternatively, the IEDs 12A and 12B may be directly connected to each other and may use any suitable communication protocol (e.g., SEL Time-Domain Link (TiDL) by Schweitzer Engineering Laboratories) to communicate voltage values. Moreover, while the IEDs 12A and 12B are shown to provide the measurements to the computer 40, the detection may be performed in a different device (e.g., the detection may be implemented in a computer with the IEDs functioning as merging units). The computer 40 may include any suitable data processing system. For example, the computer 40 may include processing circuitry 42 (e.g., a processor), memory or storage 44 (e.g., one or more tangible, non-transitory, machine-readable media) that store data and/or program instructions executable by the processing circuitry 42, as well as network communication circuitry 46 and/or input/output circuitry to communicate alarms and/or control the IEDs 12A or 12B. By correlating the measurements from the IEDs 12A and 12B in time using the common time signal from the common time source 36, the computer 40 and/or the IEDs 12A or 12B may obtain voltage differences across the transition point 16 at specific points in time. The computer 40 and/or the IEDs 12A or 12B may use these electrical measurements to detect or predict the electrical secondary arc 14 based on changes in the measurements over time.

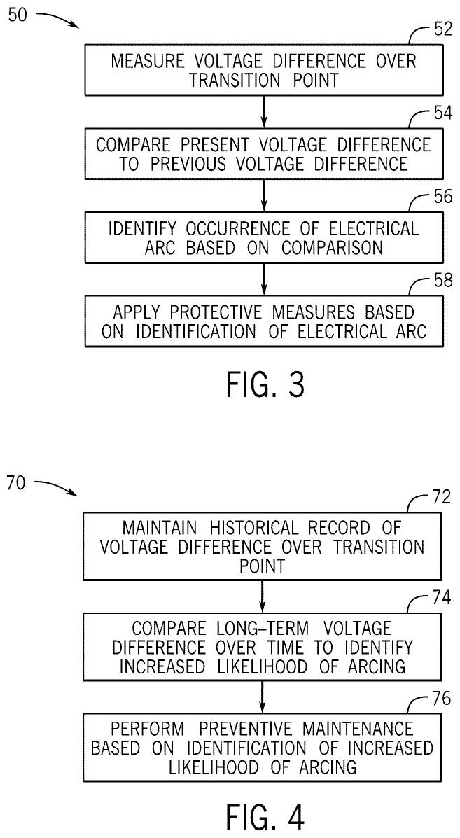

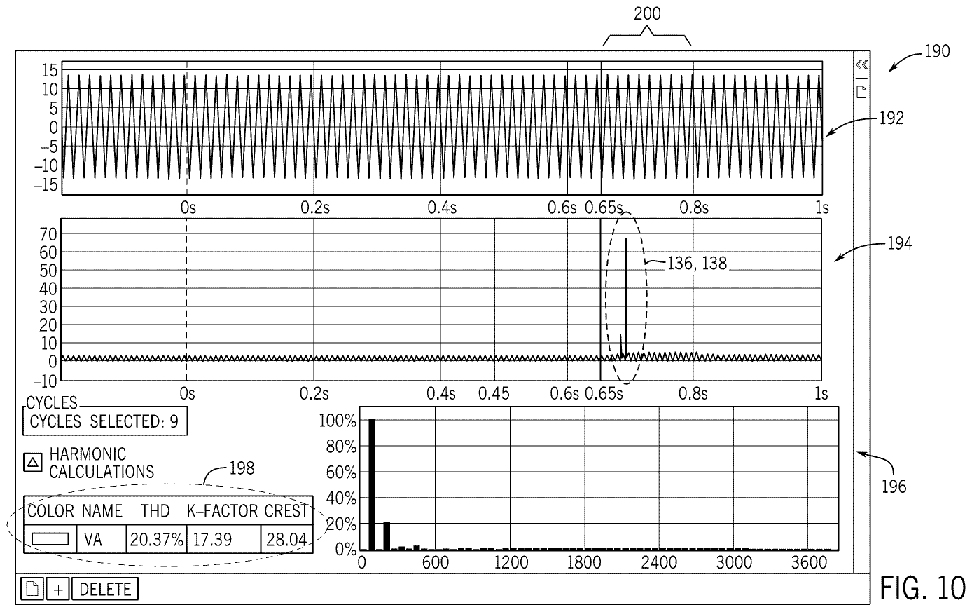

A flowchart 50 of FIG. 3 illustrates a method of detecting or predicting the occurrence of an electrical arc across a transition point based on changes in voltage difference across the transition point over time. The method of the flowchart 50 may be carried out using any suitable system, including the systems 10A of FIG. 1 or 10B of FIG. 2. The voltage difference across the transition point may be measured at different points in time (e.g., using the IED 12 as in FIG. 1 or using the IEDs 12A and 12B as in FIG. 2) (block 52). A change in voltage difference may be obtained by comparing a present voltage difference across the transition point at a first time (e.g., a most recent set of measurements) with a previous voltage difference across the transition point at a second time (e.g., a set of measurements taken an integer number of electrical cycles of the power delivery system before the present measurement, such as one electrical cycle before the present measurement) (e.g., using the IED 12, the IEDs 12A or 12B, or another data processing system such as the computer 40) (block 54).

Based on the comparison of the two values of voltage difference across the transition point at block 54, a present occurrence or likely future occurrence of an electrical secondary arc across the transition point may be identified (e.g., using the IED 12, the IEDs 12A or 12B, or another data processing system such as the computer 40) (block 56). For example, an electrical arc across the transition point may be deemed likely to be occurring when the two values of voltage difference across the transition point differ by more than a first threshold amount (e.g., more than a particular absolute voltage difference, more than a percentage voltage difference). An electrical secondary arc across the transition point may be deemed likely to occur soon in the future when the two values of voltage difference across the transition point differ by more than a second threshold amount but less than the first threshold amount (e.g., more than a particular absolute voltage difference, more than a percentage voltage difference). These thresholds may be determined through empirical testing or circuit modeling of the conductors used in the transition points. In other words, the thresholds may be selected as values that tend to occur when an electrical secondary arc occurs during empirical testing or circuit modeling. An accumulation of the difference signal may also be used.

Based on the identification of the present occurrence or likely future occurrence of the electrical secondary arc, protective measures may be undertaken (e.g., using the IED 12, the IEDs 12A or 12B, or an operator) (block 58). For example, an alarm may be set to alert an operator, a breaker (e.g., the breaker 20 of FIG. 1 or 2) may be tripped to stop electricity from flowing across the transition point, and/or equipment (e.g., equipment representing the load 24 of FIG. 1 or 2) may be power down, turned off, or switched to be supplied with electricity from a different source not traversing the transition point. Moreover, the conductors of the transition point may be replaced or cleaned to reduce the likelihood of future electrical secondary arcing across the transition point.

Additionally or alternatively, selective preventive maintenance may be performed based on monitoring historical measurements to identify when an electrical secondary arc becomes more likely to occur. Indeed, different transition points may undergo different stresses and therefore may be more or less likely to experience an electrical secondary arc than other transition points. Preventive measures may be taken, such as replacing, cleaning, or reducing the usage of these transition points to reduce the chance of an electrical secondary arc, as shown by a flowchart 70 of FIG. 4. The method of the flowchart 70 may be carried out using any suitable system, including the systems 10A of FIG. 1 or 10B of FIG. 2. For example, as shown by the flowchart 70, a historical record of voltage differences across a transition point over time may be maintained (e.g., using the IED 12, the IEDs 12A or 12B, or another data processing system such as the computer 40) (block 72). Two sets of measurements over a relatively long-term time horizon may be compared (e.g., using the IED 12, the IEDs 12A or 12B, or another data processing system such as the computer 40) to identify an increased likelihood of electrical secondary arcing (block 74). The relatively long-term time horizon may be days, weeks, or years. For example, the comparison may take place between a set of measurements obtained around the time when the transition point was originally installed (e.g., within the first few days, weeks, or months of installation) and a more recent set of measurements (e.g., a present set of measurements). In many cases, the comparison may take place between a set of measurements obtained more than a week apart, instead of around one electrical cycle in the examples of FIGS. 3 and 4.

Electrical secondary arcing may be deemed to be more likely when the present set of measurements compared to the earlier set of measurements differs by more than a threshold. Thus, the comparison of block 74 may entail determining whether the set of measurements obtained around the time when the transition point was originally installed (e.g., within the first few days, weeks, or months of installation) and the more recent set of measurements (e.g., a present set of measurements measured more recently) differ by more than the threshold. This may be due to aging of the conductors of the transition point over time. As mentioned above, advanced aging at the transition points may be caused by repeated thermal cycling, mechanical vibration, and corrosion from airborne salt often found in marine environments. The threshold may be determined through empirical testing or circuit modeling of the conductors used in the transition points to identify when an electrical secondary arc is likely to become a great enough possibility to warrant action to prevent an electrical secondary arc.

Based on the comparison at block 74, preventive measures may be undertaken (e.g., using the IED 12, the IEDs 12A or 12B, or an operator) (block 76). For example, the IED 12, the IEDs 12A or 12B, or another data processing system such as the computer 40 may issue an alarm or may schedule preventive maintenance as a result of the comparison. The transition point may be replaced, cleaned, or the load being supplied through the transition point may be reduced. This may reduce the likelihood of an electrical secondary arc ever occurring at the transition point.

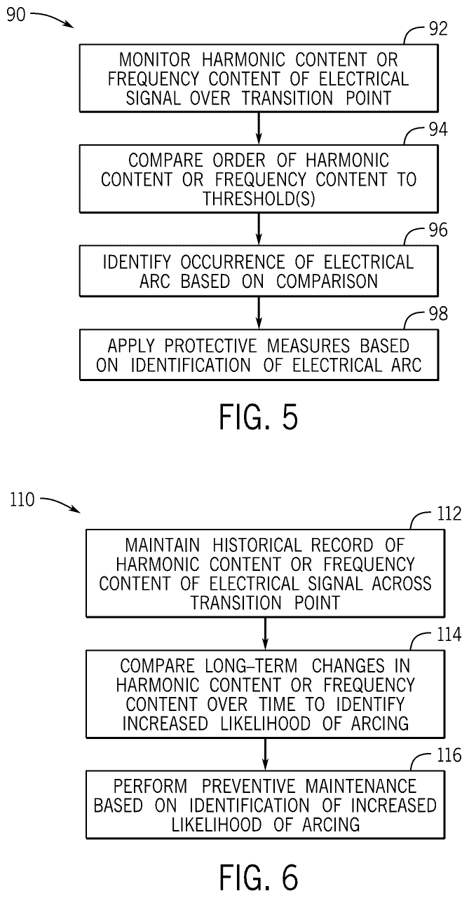

Harmonic content or frequency content of electrical measurements across a transition point may also correspond to possible electrical secondary arcing. FIGS. 5 and 6 illustrate methods for using harmonic content or frequency content of electrical measurements to identify or prevent an electrical secondary arc. In FIG. 5, a flowchart 90 illustrates a method of detecting or predicting the occurrence of an electrical secondary arc across a transition point based on changes in harmonic content or frequency content across the transition point over time. The method of the flowchart 90 may be carried out using any suitable system, including the systems 10A of FIG. 1 or 10B of FIG. 2. The harmonic content or frequency content across the transition point may be measured at different points in time (e.g., using the IED 12 as in FIG. 1 or using the IEDs 12A and 12B as in FIG. 2) (block 92). A change in harmonic content or frequency content may be obtained by comparing a present value of harmonic content or frequency content across the transition point at a first time (e.g., a most recent set of measurements) with a previous value of harmonic content or frequency content across the transition point at a second time (e.g., a set of measurements taken an integer number of electrical cycles of the power delivery system before the present measurement, such as one electrical cycle before the present measurement) (e.g., using the IED 12, the IEDs 12A or 12B, or another data processing system such as the computer 40) (block 94).

Based on the comparison of the two values of harmonic content or frequency content across the transition point at block 94, a present occurrence or likely future occurrence of an electrical secondary arc across the transition point may be identified (e.g., using the IED 12, the IEDs 12A or 12B, or another data processing system such as the computer 40) (block 96). For example, a fundamental detection principle may be the observation of higher order harmonic content in the voltage difference signal during periods of arcing than during periods of non-arcing. In other words, this may include not just that the harmonic content between the two points differ (e.g., more than a minimum threshold value), but that difference has also increased more than a separate threshold value across a selected period of time. This may entail identifying a present occurrence or likely future occurrence of an electrical secondary arc based on the accumulation (e.g., integration) of a positive difference signal. In another example, an electrical secondary arc across the transition point may be deemed likely to be occurring when the two values of harmonic content or frequency content across the transition point differ by more than a first threshold amount (e.g., more than a particular absolute change in harmonic content or frequency content, more than a percentage change in harmonic content or frequency content). In another example, an electrical secondary arc across the transition point may be deemed likely to occur soon in the future when the two values of harmonic content or frequency content across the transition point differ by more than a second threshold amount but less than the first threshold amount (e.g., more than a particular absolute voltage difference, more than a percentage voltage difference). These thresholds may be determined through empirical testing or circuit modeling of the conductors used in the transition points. In other words, the thresholds may be selected as values that tend to occur when an electrical secondary arc occurs during empirical testing or circuit modeling. Additionally or alternatively, the harmonic content or frequency content (as in the flowchart 90 of FIG. 5) may be used to verify a determination of electrical secondary arc using voltage difference (as in the flowchart 50 of FIG. 3), or vice versa. Moreover, the thresholds may be different if comparing both voltage difference and harmonic content or frequency content. For example, lower thresholds may be selected if both voltage difference and harmonic content or frequency content are compared. In some embodiments, in the presence of increased harmonic content or frequency content, the IED 12 of FIG. 1 or computer 40 of FIG. 2 may issue an alarm indicating a higher confidence that an electrical secondary arc has been detected.

Preventive measures may also be taken based on changes in harmonic content or frequency content. An example is shown by a flowchart 110 of FIG. 6. The method of the flowchart 110 may be carried out using any suitable system, including the systems 10A of FIG. 1 or 10B of FIG. 2. For example, as shown by the flowchart 110, a historical record of harmonic content or frequency content across a transition point over time may be maintained (e.g., using the IED 12, the IEDs 12A or 12B, or another data processing system such as the computer 40) (block 112). Two sets of measurements over a relatively long-term time horizon may be compared (e.g., using the IED 12, the IEDs 12A or 12B, or another data processing system such as the computer 40) to identify an increased likelihood of electrical secondary arcing (block 114). The relatively long-term time horizon may be days, weeks, or years. For example, the comparison may take place between a set of frequency or harmonic measurements obtained around the time when the transition point was originally installed (e.g., within the first few days, weeks, or months of installation) and a more recent set of frequency or harmonic measurements (e.g., a present set of frequency or harmonic measurements obtained more recently).

Electrical secondary arcing may be deemed to be more likely when the present set of frequency or harmonic measurements compared to the earlier set of frequency or harmonic measurements differs by more than a threshold. Thus, the comparison of block 114 may entail determining whether the set of frequency or harmonic measurements obtained around the time when the transition point was originally installed (e.g., within the first few days, weeks, or months of installation) and the more recent set of frequency or harmonic measurements (e.g., a present set of measurements) differ by more than the threshold. This may be due to aging of the conductors of the transition point over time. As mentioned above, advanced aging at the transition points may be caused by repeated thermal cycling, mechanical vibration, and corrosion from airborne salt often found in marine environments. The threshold may be determined through empirical testing or circuit modeling of the conductors used in the transition points to identify when an electrical secondary arc is likely to become a great enough possibility to warrant action to prevent an electrical secondary arc.

Based on the comparison at block 114, preventive measures may be undertaken (e.g., using the IED 12, the IEDs 12A or 12B, or an operator) (block 116). For example, the IED 12, the IEDs 12A or 12B, or another data processing system such as the computer 40 may issue an alarm or may schedule preventive maintenance as a result of the comparison. The transition point may be replaced, cleaned, or the load being supplied through the transition point may be reduced. This may reduce the likelihood of an electrical secondary arc ever occurring at the transition point.

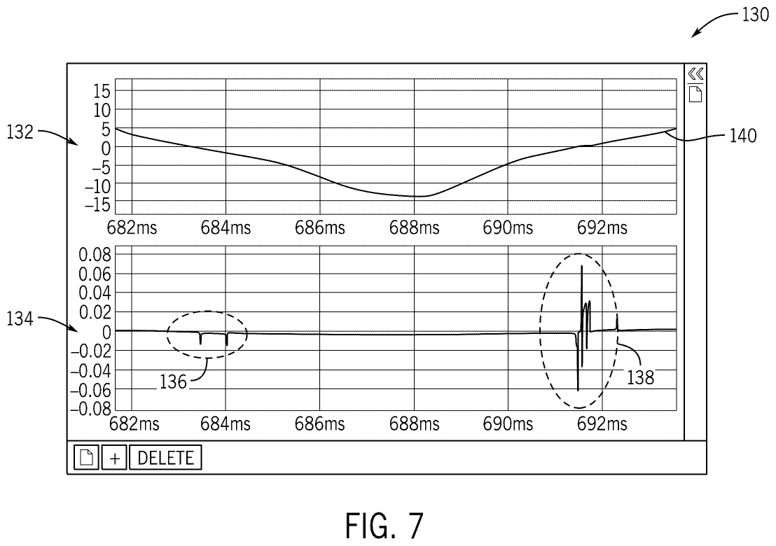

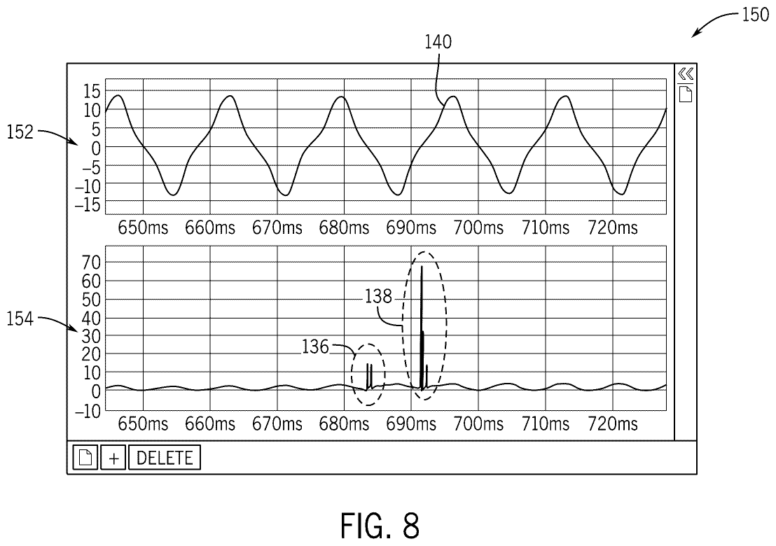

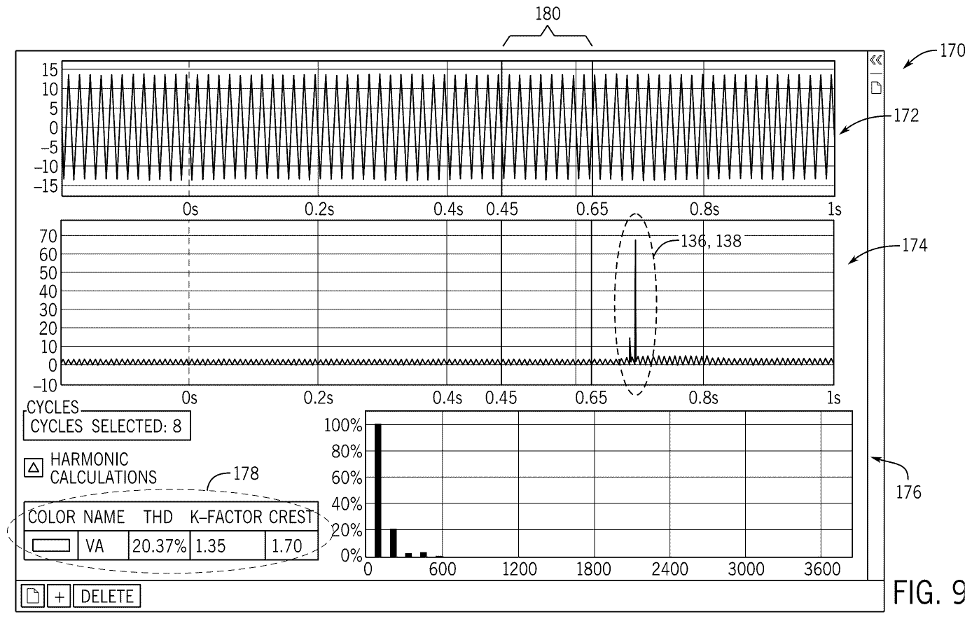

FIGS. 7 and 8 illustrate plots illustrating the relationship between voltage difference over a transition point when an electrical secondary arc occurs. Plots 130 of FIG. 7 include a current signal plot 132 and a voltage signal plot 134. The current signal plot 132 illustrates a change in current 140 illustrating an arcing signature voltage difference across the transition point. As seen in the voltage signal plot 134, when the transition point begins to break down before an arc occurs, the voltage difference begins to vary from normal (region 136, which indicates low magnitude secondary arcing). When a large secondary electrical arc occurs, the voltage difference across the transition point varies dramatically (region 138). Plots 150 of FIG. 8 shows an absolute value of voltage difference when the electrical secondary arc shown in FIG. 7 occurs. The plots 150 of FIG. 8 include a current signal plot 152 and an absolute voltage signal difference plot 154 over a longer time scale than the plots 130 of FIG. 7. The current signal plot 152 illustrates the current 140 flowing over the transition point and the absolute voltage difference plot 154 illustrates change in absolute voltage across the transition point. In the absolute voltage difference plot 154, the regions 136 and 138 can be seen more clearly since these represent absolute values of voltage difference.

Considering the plots 130 of FIGS. 7 and 150 of FIG. 8 in the context of the flowcharts 50 of FIGS. 3 and 70 of FIG. 4, an electrical arc may be detected based on the voltage differences shown at regions 136 and/or 138. For example, a data processing system (e.g., the IED 12, 12A, or 12B, or the computer 40) may determine that the voltage difference of the region 136 has crossed a threshold that causes the data processing system to carry out or prescribe protective measures to prevent damage from an electrical secondary arc from occurring. Additionally or alternatively, a data processing system (e.g., the IED 12, 12A, or 12B, or the computer 40) may determine that the voltage difference of the region 138 has crossed a threshold that causes the data processing system to identify that an electrical arc is occurring and carry out or prescribe protective measures to stop it.

FIGS. 9 and 10 are plots illustrating the relationship between harmonic content or frequency content of electrical signals over a transition point when an electrical arc occurs. Plots 170 of FIG. 9 include an electrical current 172 representing electrical current flowing over the transition point, a voltage difference plot 174 representing voltage difference across the transition point, and a harmonic content plot 176 representing harmonic content across the transition point. The plots 170 illustrate an average measurement of harmonic content 178 over a window 180 occurring before the electrical secondary arc occurring at regions 136, 138. Here, the average measurement of harmonic content is measured to be a total harmonic distortion (THD) of 20.37%, with a k-factor of 1.35 and a crest of 1.70. This changes dramatically during and/or after an electrical arc, as illustrated by plots 190 of FIG. 10. The plots 190 include an electrical current plot 192 representing electrical current flowing over the transition point, a voltage difference plot 194 representing voltage difference across the transition point, and a harmonic content plot 196 representing harmonic content across the transition point. The plots 190 illustrate an average measurement of harmonic content 198 over a window 200 occurring while the electrical secondary arc occurs at regions 136, 138. Here, the average measurement of harmonic content is measured to be a total harmonic distortion (THD) of 23.70%, with a k-factor of 17.39 and a crest of 34.64.

Considering the plots 170 of FIGS. 9 and 190 of FIG. 10 in the context of the flowcharts 90 of FIGS. 5 and 110 of FIG. 6, an electrical secondary arc may be detected based on the harmonic content or frequency content changes starting around regions 136 and/or 138. For example, a data processing system (e.g., the IED 12, 12A, or 12B, or the computer 40) may determine that the harmonic content or frequency content has changed beyond a threshold that causes the data processing system to carry out or prescribe protective measures to prevent or stop an electrical arc from occurring. Additionally or alternatively, a data processing system (e.g., the IED 12, 12A, or 12B, or the computer 40) may determine that the harmonic content or frequency content of the region 138 has crossed a threshold that causes the data processing system to identify that an electrical arc is occurring and carry out or prescribe protective measures to stop it.

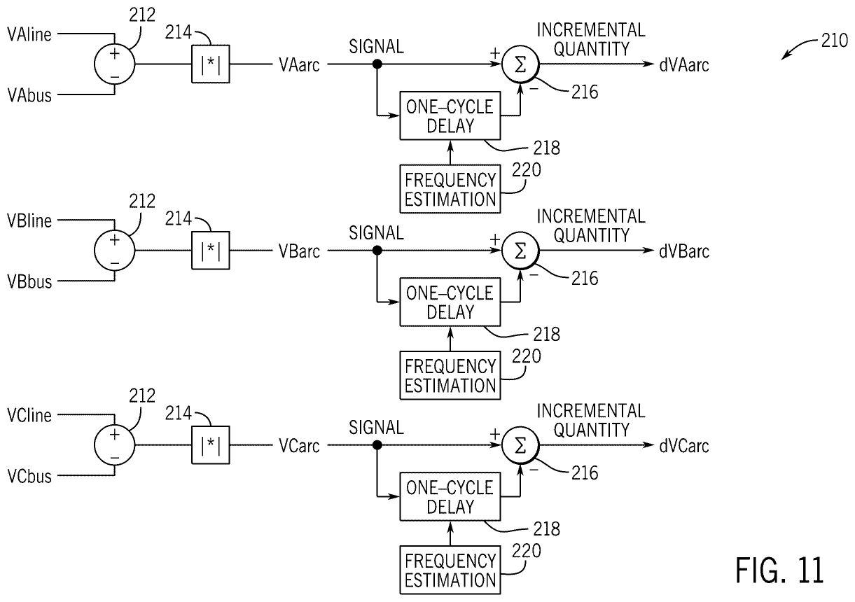

Any suitable computer program or circuitry may carry out the systems and methods discussed above. FIG. 11 illustrates a schematic diagram of a system 210 that may be used to obtain voltage difference values for use to identify when an electrical arc is occurring or is likely to occur in the future. The system 210 may receive measurements of voltage of each phase on each side of the transition point (e.g., for phase A, line voltage VAline and bus voltage VAbus; for phase B, line voltage VBline and bus voltage VBbus; and for phase C, line voltage VCline and bus voltage VCbus). The respective values for each phase may feed into subtractors 212 in to obtain the signed voltage difference across the transition point by phase, the results of which may be converted to absolute values 214 (e.g., VAarc, VBarc, and VCarc). For each phase, from each present absolute value 214, a prior measurement may be subtracted 216. The prior measurement may be one from a delay 218 (e.g., a one cycle-delay, a two cycle-delay) defined by a frequency estimation 220 based on the electrical signal. The resulting change in voltage difference signal (e.g., dVAarc, dVBarc, dVCarc) may be output by the system 210. In other examples, a prior average measurement (e.g., an average of the most recent N cycles, where N is a window size that may be selected based on empirical results or computer modeling) may be subtracted from the present absolute value 214 to obtain the change in voltage difference signal.

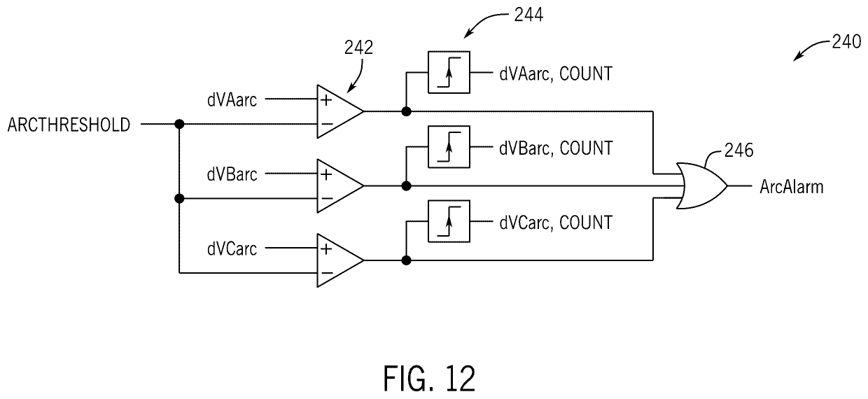

As shown by an alarm system 240 of FIG. 12, the change in voltage difference signal (e.g., dVAarc, dVBarc, dVCarc) may be compared in comparators 242 to a threshold value (e.g., arcthreshold). When any of the change in voltage difference signals (e.g., dVAarc, dVBarc, dVCarc) exceeds the threshold (e.g., arcthreshold), a counter 244 may increment and based on an OR operator 246, an alarm may be issued. The alarm may cause an IED to take immediate remedial action (e.g., trip a breaker of the transition point) and/or may alert an operator to take action to address likely the electrical secondary arc on that phase.

While specific embodiments and applications of the disclosure have been illustrated and described, it is to be noted that the disclosure is not limited to the precise configurations and devices disclosed herein. Accordingly, many changes may be made to the details of the above-described embodiments without departing from the underlying principles of this disclosure. The scope of the present disclosure should, therefore, be determined only by the following claims.

Indeed, the embodiments set forth in the present disclosure may be susceptible to various modifications and alternative forms, specific embodiments have been shown by way of example in the drawings and have been described in detail herein. However, it may be noted that the disclosure is not intended to be limited to the particular forms disclosed. The disclosure is to cover all modifications, equivalents, and alternatives falling within the spirit and scope of the disclosure as defined by the following appended claims. In addition, the techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). For any claims containing elements designated in any other manner, however, it is intended that such elements are not to be interpreted under 35 U.S.C. 112(f).

What is claimed is:

1. An intelligent electronic device (IED) for an electric power delivery system, the IED comprising:
data processing circuitry; and
one or more tangible, non-transitory, machine readable media comprising instructions that, when executed by the data processing circuitry, cause the IED to perform operations comprising:
comparing a first electrical measurement across a transition point formed by a plurality of connected conductors in the electric power delivery system measured at a first time with a second electrical measurement across the transition point measured at a second time; and
identifying an occurrence of an electrical secondary arc across the transition point when the second electrical measurement at the second time is greater than the first electrical measurement at the first time by more than a threshold.

2. The IED of claim 1, wherein the first electrical measurement across the transition point comprises a first voltage difference across the transition point at the first time and the second electrical measurement across the transition point comprises a second voltage difference across the transition point at the second time.

3. The IED of claim 2, wherein the instructions, when executed by the data processing circuitry, cause the IED to perform operations comprising:
determining the first voltage difference by subtracting a first voltage measurement obtained from a first side of the transition point at the first time from a first voltage measurement obtained from a second side of the transition point at the first time; and
determining the second voltage difference by subtracting a second voltage measurement obtained from the second side of the transition point at the second time from a second voltage measurement obtained from the second side of the transition point at the second time.

4. The IED of claim 3, wherein the IED comprises communication circuitry to receive:
the first voltage measurement obtained at the first time from the first side of the transition point from a first potential transformer;
the second voltage measurement obtained at the second time from the first side of the transition point from the first potential transformer;
the first voltage measurement obtained at the first time from the second side of the transition point from a second potential transformer; and
the second voltage measurement obtained at the second time from the second side of the transition point from the second potential transformer; and
wherein the transition point is disposed between an electrical bus and a circuit breaker.

5. The IED of claim 3, comprising network circuitry to receive, from another IED, at least one of:
the first voltage measurement obtained at the first time from the first side of the transition point and the second voltage measurement obtained at the second time from the first side of the transition point; or
the first voltage measurement obtained at the first time from the second side of the transition point and the second voltage measurement obtained at the second time from the second side of the transition point.

6. The IED of claim 1, wherein the first electrical measurement across the transition point comprises a first measurement of harmonic content across the transition point at the first time and the second electrical measurement across the transition point comprises a second measurement of harmonic content across the transition point at the second time.

7. The IED of claim 1, wherein comparing the first electrical measurement with the second electrical measurement comprises accumulating a positive difference signal between the first electrical measurement and the second electrical measurement.

8. The IED of claim 1, wherein the first electrical measurement across the transition point comprises a plurality of electrical values corresponding to different phases of multiphase power that flows over the transition point.

9. The IED of claim 1, wherein the instructions, when executed by the data processing circuitry, cause the IED to perform operations comprising:
based on the identification of the occurrence of the electrical secondary arc across the transition point, controlling a component of the electric power delivery system to mitigate an impact of the electrical secondary arc.

10. The IED of claim 9, wherein controlling the component of the electric power delivery system comprises tripping a circuit breaker.

11. A method comprising:
obtaining electrical measurements across a transition point between a bus of an electric power delivery system and a circuit breaker at a first time;
obtaining electrical measurements across the transition point between the bus of the electric power delivery system and the circuit breaker at a second time;
determining a difference between the electrical measurements obtained at the first time and the electrical measurements obtained at the second time; and
undertaking protective measures or preventive maintenance to mitigate an electric secondary arc across the transition point based on the difference between the electrical measurements obtained at the first time and the electrical measurements obtained at the second time exceeding a threshold value.

12. The method of claim 11, wherein the first time and the second time are separated by an integer number of electrical cycles of the power delivery system.

13. The method of claim 12, wherein the protective measures comprise tripping a circuit breaker.

14. The method of claim 11, wherein the first time and the second time are separated by at least one week.

15. The method of claim 14, wherein the preventive maintenance comprises replacing or cleaning conductors of the transition point to prevent the electrical secondary arc across the transition point from occurring.

16. An article of manufacture comprising one or more tangible, non-transitory, machine-readable media comprising instructions that, when executed by a data processing system, cause the data processing system to:
receive a first electrical measurement across a transition point conductor in an electric power delivery system obtained at a first time;
receive a second electrical measurement across the transition point conductor obtained at a second time, wherein the second time is after the first time;
based on the second electrical measurement being more than a threshold value higher than the first measurement, identify an electrical secondary arc across the transition point conductor; and
based on the identification of the electrical secondary arc across the transition point conductor, provide a signal indicative of a protective action to mitigate the electrical secondary arc.

17. The article of manufacture of claim 16, wherein the first electrical measurement and the second electrical measurement comprise measurements of voltage difference across the transition point conductor.

18. The article of manufacture of claim 16, wherein the first electrical measurement and the second electrical measurement comprise measurements of harmonic content or frequency content across the transition point conductor.

19. The article of manufacture of claim 16, wherein providing the signal indicative of the protective action comprises issuing an alarm to alert an operator that the electrical secondary arc has been detected.

20. The article of manufacture of claim 16, wherein providing the signal indicative of the protective action comprises issuing a control signal to control a circuit breaker to disconnect the transition point conductor from a load.
